(19) United States
(12) Patent Application Publication
(10) Pub. No.: US 2026/0107813 A1
(43) Pub. Date: Apr. 16, 2026

(54) CHIP PACKAGE STRUCTURE

(71) Applicant: inergy Technology Inc., Hsinchu County (TW)

(72) Inventors: Li-Zheng LIN, Hsinchu County (TW); Nan-Wei WEN, Hsinchu County (TW)

(21) Appl. No.: 19/248,440

(22) Filed: Jun. 24, 2025

(30) Foreign Application Priority Data
Oct. 16, 2024 (TW) 113211239

(51) Int. Cl. H01L 23/00; H01L 23/495

(52) U.S. Cl. CPC H10W 72/50; H10W 70/481; H10W 72/5445; H10W 90/756

(57) ABSTRACT

A chip package structure includes a conductive substrate, a chip, a gate connecting part, a source connecting part, a drain connecting part, a gate conductive wire, a source conductive wire, and a plurality of pins. The gate connecting part is located at a side of the chip. The source connecting part is located at the side of the chip and is separated from the gate connecting part. The source conductive wire is connected to a source electrode of the chip and the source connecting part. The pins include a first pin, a second pin, and one or more third pins. The first pin is connected to the gate connecting part. The second pin is connected to the one or more third pins by the source connecting part.

### CROSS-REFERENCE TO RELATED APPLICATION

This application claims priority to Taiwan Application Serial Number 113211239, filed October 16, 2024, which is herein incorporated by reference in its entirety.

### BACKGROUND

### Field of Invention

The present invention relates to a chip package structure.

### Description of Related Art

In general, chip package technology has evolved along with the improvement of chip performance. However, as chips continue to be miniaturized, the quantity of the chips that can be mounted increases, and operating speeds keep rising. As a result, issues such as high power consumption and the generation of large amounts of waste heat have emerged.

Therefore, how to propose a chip package structure that can solve the aforementioned problems is one of the problems that the industry is currently eager to invest in research and development resources to solve.

### SUMMARY

In view of this, one purpose of the present disclosure is to provide a chip package structure that can solve the aforementioned problems.

In order to achieve the above objective, in accordance with an embodiment of the present disclosure, a chip package structure includes a conductive substrate, a chip, a gate connecting part, a source connecting part, a drain connecting part, a gate conductive wire, a source conductive wire, and a plurality of pins. The chip is disposed on the conductive substrate. The gate connecting part is located at a side of the chip. The source connecting part is located at the side of the chip and is separated from the gate connecting part. The drain connecting part is connected to the conductive substrate and is located at the other side of the chip. The gate conductive wire is connected to a gate electrode of the chip and the gate connecting part. The source conductive wire is connected to a source electrode of the chip and the source connecting part. The pins are connected to the gate connecting part and the source connecting part. The pins include a first pin, a second pin, and one or more third pins. The first pin is connected to the gate connecting part. The second pin is connected to the source connecting part and is separated from the first pin. The one or more third pins are separated from the first pin and the second pin. The second pin is connected to the one or more third pins by the source connecting part.

In one or more embodiments of the present disclosure, the source conductive wire is electrically connected to the one or more third pins by the source connecting part.

In one or more embodiments of the present disclosure, the gate conductive wire is electrically connected to the first pin by the gate connecting part.

In one or more embodiments of the present disclosure, the chip package structure further includes a sense conductive wire connected to the source electrode and the source connecting part.

In one or more embodiments of the present disclosure, the sense conductive wire is separated from the source conductive wire.

In one or more embodiments of the present disclosure, the sense conductive wire is electrically connected to the second pin by the source connecting part.

In one or more embodiments of the present disclosure, the sense conductive wire is separated from the gate conductive wire.

In one or more embodiments of the present disclosure, the gate conductive wire is separated from the source conductive wire.

In one or more embodiments of the present disclosure, the first pin is located at a side of the gate connecting part away from the chip, and the second pin and the one or more third pins are located at a side of the source connecting part away from the chip.

In one or more embodiments of the present disclosure, the second pin is located between the first pin and the one or more third pins.

In order to achieve the above objective, in accordance with an embodiment of the present disclosure, a chip package structure includes a conductive substrate, a chip, a gate connecting part, a source connecting part, a drain connecting part, a gate conductive wire, a source conductive wire, and a plurality of pins. The chip is disposed on the conductive substrate. The gate connecting part is located at a side of the chip. The source connecting part is separated from the gate connecting part. The drain connecting part is electrically connected to a drain electrode of the chip by the conductive substrate. The gate conductive wire is connected to a gate electrode of the chip and the gate connecting part. The source conductive wire is connected to a source electrode of the chip and the source connecting part. The pins are connected to the gate connecting part and the source connecting part. The pins include a first pin, a second pin, and one or more third pins. The first pin is connected to the gate connecting part. The second pin is connected to the source connecting part and is separated from the first pin. The one or more third pins are separated from the first pin and the second pin. The second pin is connected to the one or more third pins by the source connecting part.

In one or more embodiments of the present disclosure, the source conductive wire is electrically connected to the one or more third pins by the source connecting part.

In one or more embodiments of the present disclosure, the gate conductive wire is electrically connected to the first pin by the gate connecting part.

In one or more embodiments of the present disclosure, the chip package structure further includes a sense conductive wire connected to the source electrode and the source connecting part.

In one or more embodiments of the present disclosure, the sense conductive wire is separated from the source conductive wire.

In one or more embodiments of the present disclosure, the sense conductive wire is electrically connected to the second pin by the source connecting part.

In one or more embodiments of the present disclosure, the sense conductive wire is separated from the gate conductive wire.

In one or more embodiments of the present disclosure, the gate conductive wire is separated from the source conductive wire.

In one or more embodiments of the present disclosure, the first pin is located at a side of the gate connecting part away from the chip, and the second pin and the one or more third pins are located at a side of the source connecting part away from the chip.

In one or more embodiments of the present disclosure, the second pin is located between the first pin and the one or more third pins.

In summary, in the chip package structure of the present disclosure, since the second pin is connected to the source connecting part, the volume of the source connecting part, which is originally connected to the one or more third pins, is increased, thereby achieving the effect of enlarging the wire bonding area and increasing the quantity of bonding wires. Accordingly, the chip package structure of the present disclosure can effectively reduce the resistance of the chip to meet consumer’s demands.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a chip package structure in accordance with an embodiment of the present disclosure;

FIG. 2 is a top view of a chip package structure in accordance with an embodiment of the present disclosure;

FIG. 3 is a top view of a chip package structure in accordance with an embodiment of the present disclosure; and

FIG. 4 is a top view of a chip package structure in accordance with an embodiment of the present disclosure.

### DETAILED DESCRIPTION

Hereinafter, a plurality of embodiments of the present disclosure will be disclosed in diagrams. For the sake of clarity, many details in practice will be described in the following description. However, it should be understood that these details in practice should not limit present disclosure. In other words, in some embodiments of present disclosure, these details in practice are unnecessary. In addition, for simplicity of the drawings, some conventionally used structures and elements will be shown in a simple schematic manner in the drawings. The same reference numbers are used in the drawings and the description to refer to the same or like parts.

Hereinafter, the structure, function, and connection relationships of each component included in a chip package structure 100 of this embodiment will be described in detail.

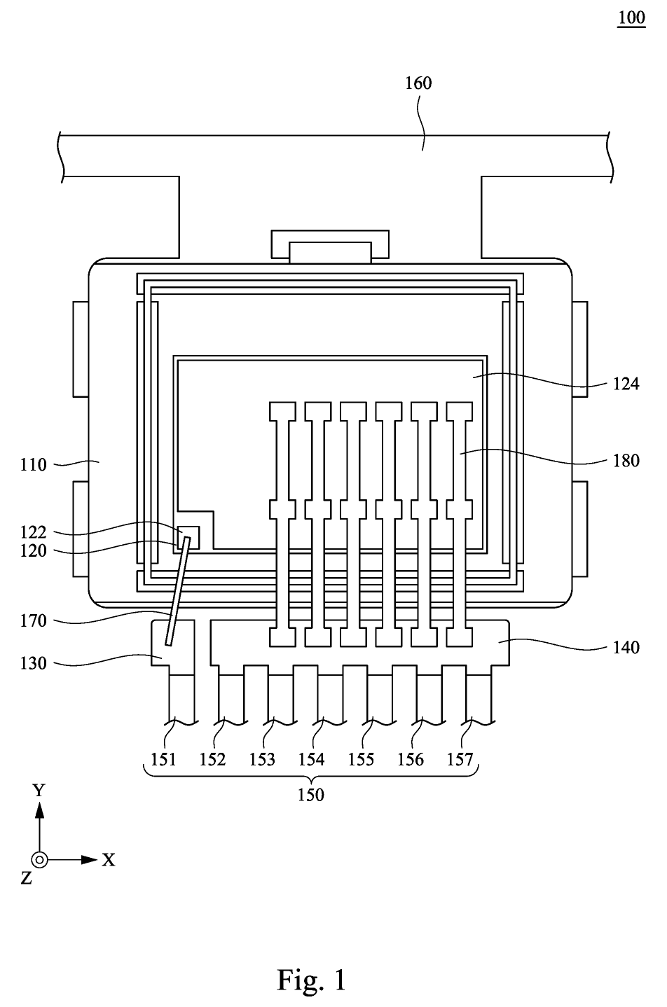

Reference is made to FIG. 1. FIG. 1 is a top view of a chip package structure 100 in accordance with an embodiment of the present disclosure. As shown in FIG. 1, in this embodiment, the chip package structure 100 includes a conductive substrate 110, a chip 120, a gate connecting part 130, a source connecting part 140, a plurality of pins 150, a drain connecting part 160, a gate conductive wire 170, and a source conductive wire 180. The chip 120 is disposed on the conductive substrate 110. The chip 120 includes a gate electrode 122, a source electrode 124, and a drain electrode (not shown). Specifically, the gate electrode 122 is separated from the source electrode 124. The drain electrode is also separated from the source electrode 124. As shown in FIG. 1, in some embodiments, the gate electrode 122 and the source electrode 124 are located on an upper surface (e.g., a front surface) of the chip 120, and the drain electrode is located on a lower surface (e.g., a back surface) of the chip 120. Therefore, in such a case, the drain electrode of the chip 120 is not visible in FIG. 1. In some embodiments, the drain electrode of the chip 120 is in contact with the conductive substrate 110. The gate connecting part 130 is located at a side of the chip 120. In some embodiments, the gate connecting part 130 is adjacent to the conductive substrate 110 and the chip 120. In some embodiments, the gate connecting part 130 is separated from the conductive substrate 110, and the gate connecting part 130 is also separated from the chip 120. The source connecting part 140 is located at a side of the chip 120. Specifically, the gate connecting part 130 and the source connecting part 140 are located at the same side of the chip 120. The source connecting part 140 is separated from the gate connecting part 130. The plurality of pins 150 are connected to the gate connecting part 130 and the source connecting part 140. In this embodiment, the plurality of pins 150 include a first pin 151, a second pin 152, a third pin 153, a fourth pin 154, a fifth pin 155, a sixth pin 156, and a seventh pin 157. The first pin 151 is connected to the gate connecting part 130. The second pin 152, the third pin 153, the fourth pin 154, the fifth pin 155, the sixth pin 156, and the seventh pin 157 are connected to the source connecting part 140. As shown in FIG. 1, the first pin 151, the second pin 152, the third pin 153, the fourth pin 154, the fifth pin 155, the sixth pin 156, and the seventh pin 157 are separated from each other. In other words, the third pin 153, the fourth pin 154, the fifth pin 155, the sixth pin 156, and the seventh pin 157 are connected to the second pin 152 by the source connecting part 140.

Reference is made again to FIG. 1. As shown in FIG. 1, in this embodiment, the drain connecting part 160 is connected to the conductive substrate 110. The drain connecting part 160 is located at the other side of the chip 120. In other words, the source connecting part 140 and the drain connecting part 160 are located at opposite sides of the chip 120. In some embodiments, the drain connecting part 160 is electrically connected to the drain electrode (not shown) of the chip 120 by the conductive substrate 110. The gate conductive wire 170 is connected to the gate electrode 122 of the chip 120 and the gate connecting part 130. Specifically, an end of the gate conductive wire 170 is connected to the gate electrode 122, and the other end of the gate conductive wire 170 is connected to the gate connecting part 130, such that the gate electrode 122 is electrically connected to the gate connecting part 130 by the gate conductive wire 170. The gate conductive wire 170 is electrically connected to the first pin 151 by the gate connecting part 130. The gate conductive wire 170 is separated from the source conductive wire 180. The source conductive wire 180 is connected to the source electrode 124 of the chip 120 and the source connecting part 140. Specifically, an end of the source conductive wire 180 is connected to the source electrode 124, and the other end of the source conductive wire 180 is connected to the source connecting part 140, such that the source electrode 124 is electrically connected to the source connecting part 140 by the source conductive wire 180. The source conductive wire 180 is electrically connected to the third pin 153, the fourth pin 154, the fifth pin 155, the sixth pin 156, and the seventh pin 157 by the source connecting part 140.

By the aforementioned structural configuration, since the second pin 152, which is configured as a sense source pin, is connected to the source connecting part 140, the volume of the source connecting part 140, which is originally connected to the third pin 153, the fourth pin 154, the fifth pin 155, the sixth pin 156, and the seventh pin 157, which are configured as source pins, is increased, thereby achieving the effect of enlarging the wire bonding area and increasing the quantity of bonding wires, which in turn reduces the resistance of the chip 120. Accordingly, the chip package structure 100 is feasible for applications in medium-voltage and low-voltage products.

As shown in FIG. 1, in some embodiments, the first pin 151 is located at a side of the gate connecting part 130 away from the chip 120. The second pin 152, the third pin 153, the fourth pin 154, the fifth pin 155, the sixth pin 156, and the seventh pin 157 are located at a side of the source connecting part 140 away from the chip 120.

As shown in FIG. 1, in some embodiments, the second pin 152 is located between the first pin 151 and the third pin 153.

In some embodiments, the quantity of the pins 150 is plural. For example, the chip package structure 100 may include seven pins 150. However, the present disclosure is not intended to limit the quantity of the pins 150.

In some embodiments, the first pin 151 may be, for example, a gate pin. In some embodiments, the second pin 152 may be, for example, a sense source pin. In some embodiments, the third pin 153, the fourth pin 154, the fifth pin 155, the sixth pin 156, and the seventh pin 157 may be, for example, source pins.

As shown in FIG. 1, in some embodiments, the conductive substrate 110, the chip 120, and the source conductive wire 180 are sequentially arranged along a direction (e.g., a Z-direction). In some embodiments, the first pin 151, the second pin 152, the third pin 153, the fourth pin 154, the fifth pin 155, the sixth pin 156, and the seventh pin 157 are arranged along a direction (e.g., an X-direction). In some embodiments, a plurality of the source conductive wires 180 are arranged along a direction (e.g., an X-direction) and are elongated in another direction (e.g., a Y-direction).

In some embodiments, the quantity of the gate conductive wire 170 may be singular. In some embodiments, the quantity of the source conductive wire 180 may be one, two, three, four, five, six, or more than six. However, the present disclosure is not intended to limit the quantities of the gate conductive wire 170 and the source conductive wire 180.

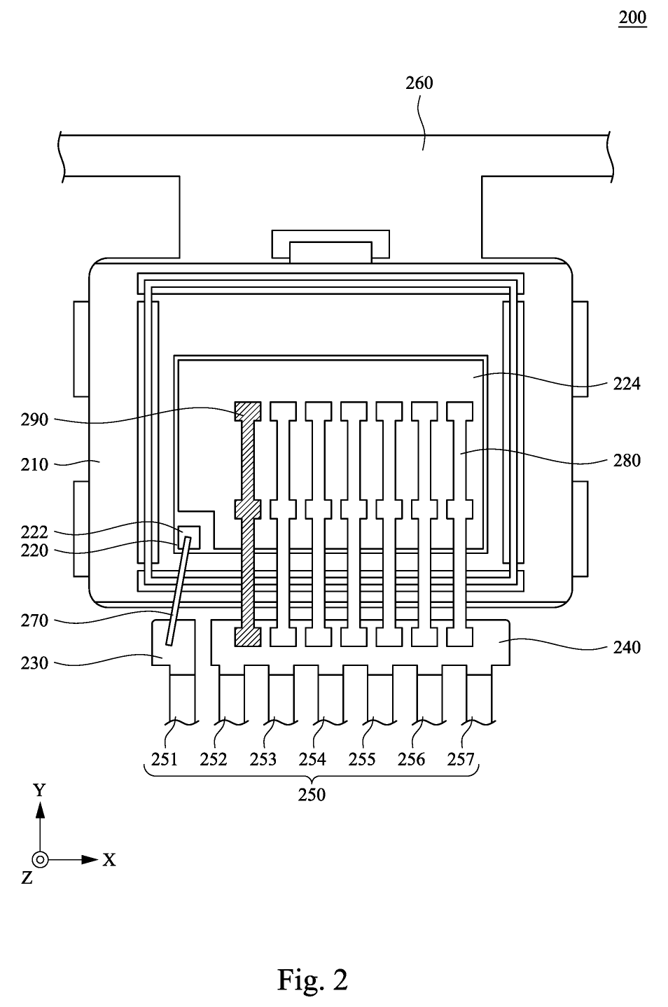

Reference is made to FIG. 2. FIG. 2 is a top view of a chip package structure 200 in accordance with an embodiment of the present disclosure. As shown in FIG. 2, in this embodiment, the chip package structure 200 includes a conductive substrate 210, a chip 220, a gate connecting part 230, a source connecting part 240, a plurality of pins 250, a drain connecting part 260, a gate conductive wire 270, a source conductive wire 280, and a sense conductive wire 290. The chip 220 is disposed on the conductive substrate 210. The chip 220 includes a gate electrode 222, a source electrode 224, and a drain electrode (not shown). It should be noted that, since the structural configuration of the chip 220 is the same as that of the chip 120, further description of the chip 220 is omitted. In some embodiments, the drain electrode of the chip 220 is in contact with the conductive substrate 210. The gate connecting part 230 is located at a side of the chip 220. In some embodiments, the gate connecting part 230 is adjacent to the conductive substrate 210 and the chip 220. In some embodiments, the gate connecting part 230 is separated from the conductive substrate 210, and the gate connecting part 230 is also separated from the chip 220. The source connecting part 240 is located at a side of the chip 220. Specifically, the gate connecting part 230 and the source connecting part 240 are located at the same side of the chip 220. The source connecting part 240 is separated from the gate connecting part 230. The plurality of pins 250 are connected to the gate connecting part 230 and the source connecting part 240. In this embodiment, the plurality of pins 250 include a first pin 251, a second pin 252, a third pin 253, a fourth pin 254, a fifth pin 255, a sixth pin 256, and a seventh pin 257. The first pin 251 is connected to the gate connecting part 230. The second pin 252, the third pin 253, the fourth pin 254, the fifth pin 255, the sixth pin 256, and the seventh pin 257 are connected to the source connecting part 240. As shown in FIG. 2, the third pin 253, the fourth pin 254, the fifth pin 255, the sixth pin 256, and the seventh pin 257 are connected to the second pin 252 by the source connecting part 240.

Reference is made again to FIG. 2. As shown in FIG. 2, in this embodiment, the drain connecting part 260 is connected to the conductive substrate 210. The drain connecting part 260 is located at the other side of the chip 220. In other words, the source connecting part 240 and the drain connecting part 260 are located at opposite sides of the chip 220. In some embodiments, the drain connecting part 260 is electrically connected to the drain electrode (not shown) of the chip 220 by the conductive substrate 210. The gate conductive wire 270 is connected to the gate electrode 222 of the chip 220 and the gate connecting part 230. Specifically, an end of the gate conductive wire 270 is connected to the gate electrode 222, and the other end of the gate conductive wire 270 is connected to the gate connecting part 230, such that the gate electrode 222 is electrically connected to the gate connecting part 230 by the gate conductive wire 270. The gate conductive wire 270 is electrically connected to the first pin 251 by the gate connecting part 230. The gate conductive wire 270 is separated from the source conductive wire 280. The source conductive wire 280 is connected to the source electrode 224 of the chip 220 and the source connecting part 240. Specifically, an end of the source conductive wire 280 is connected to the source electrode 224, and the other end of the source conductive wire 280 is connected to the source connecting part 240, such that the source electrode 224 is electrically connected to the source connecting part 240 by the source conductive wire 280. The source conductive wire 280 is electrically connected to the third pin 253, the fourth pin 254, the fifth pin 255, the sixth pin 256, and the seventh pin 257 by the source connecting part 240.

Reference is made again to FIG. 2. As shown in FIG. 2, in this embodiment, the sense conductive wire 290 is connected to the source electrode 224 and the source connecting part 240. Specifically, the sense conductive wire 290 is connected to the source electrode 224 of the chip 220 and the source connecting part 240. Specifically, an end of the sense conductive wire 290 is connected to the source electrode 224, and the other end of the sense conductive wire 290 is connected to the source connecting part 240, such that the source electrode 224 is electrically connected to the source connecting part 240 by the sense conductive wire 290. In some embodiments, the sense conductive wire 290 is electrically connected to the second pin 252 by the source connecting part 240. The sense conductive wire 290 is separated from the source conductive wire 280, and the sense conductive wire 290 is also separated from the gate conductive wire 270.

By the aforementioned structural configuration, since the second pin 252, which is configured as a sense source pin, is connected to the source connecting part 240, the volume of the source connecting part 240, which is originally connected to the third pin 253, the fourth pin 254, the fifth pin 255, the sixth pin 256, and the seventh pin 257, which are configured as source pins, is increased, thereby achieving the effect of enlarging the wire bonding area and increasing the quantity of bonding wires, which in turn reduces the resistance of the chip 220. For example, the chip package structure 200 allows for the arrangement of the sense conductive wire 290, thereby achieving an increased number of bonding wires. Accordingly, the chip package structure 200 is feasible for applications in medium-voltage and low-voltage products.

As shown in FIG. 2, in some embodiments, the first pin 251 is located at a side of the gate connecting part 230 away from the chip 220. The second pin 252, the third pin 253, the fourth pin 254, the fifth pin 255, the sixth pin 256, and the seventh pin 257 are located at a side of the source connecting part 240 away from the chip 220.

As shown in FIG. 2, in some embodiments, the second pin 252 is located between the first pin 251 and the third pin 253.

In some embodiments, the quantity of the pins 250 is plural. For example, the chip package structure 200 may include seven pins 250. However, the present disclosure is not intended to limit the quantity of the pins 250.

In some embodiments, the first pin 251 may be, for example, a gate pin. In some embodiments, the second pin 252 may be, for example, a sense source pin. In some embodiments, the third pin 253, the fourth pin 254, the fifth pin 255, the sixth pin 256, and the seventh pin 257 may be, for example, source pins.

As shown in FIG. 2, in some embodiments, the conductive substrate 210, the chip 220, and the source conductive wire 280 are sequentially arranged along a direction (e.g., a Z-direction). In some embodiments, the first pin 251, the second pin 252, the third pin 253, the fourth pin 254, the fifth pin 255, the sixth pin 256, and the seventh pin 257 are arranged along a direction (e.g., an X-direction). In some embodiments, the source conductive wire 280 and the sense conductive wire 290 are arranged along a direction (e.g., an X-direction) and are elongated in another direction (e.g., a Y-direction).

In some embodiments, the quantity of the gate conductive wire 270 may be singular. In some embodiments, the quantity of the source conductive wire 280 may be one, two, three, four, five, six, or more than six. In some embodiments, the quantity of the sense conductive wire 290 may be one or more than one. However, the present disclosure is not intended to limit the quantities of the gate conductive wire 270, the source conductive wire 280, and the sense conductive wire 290.

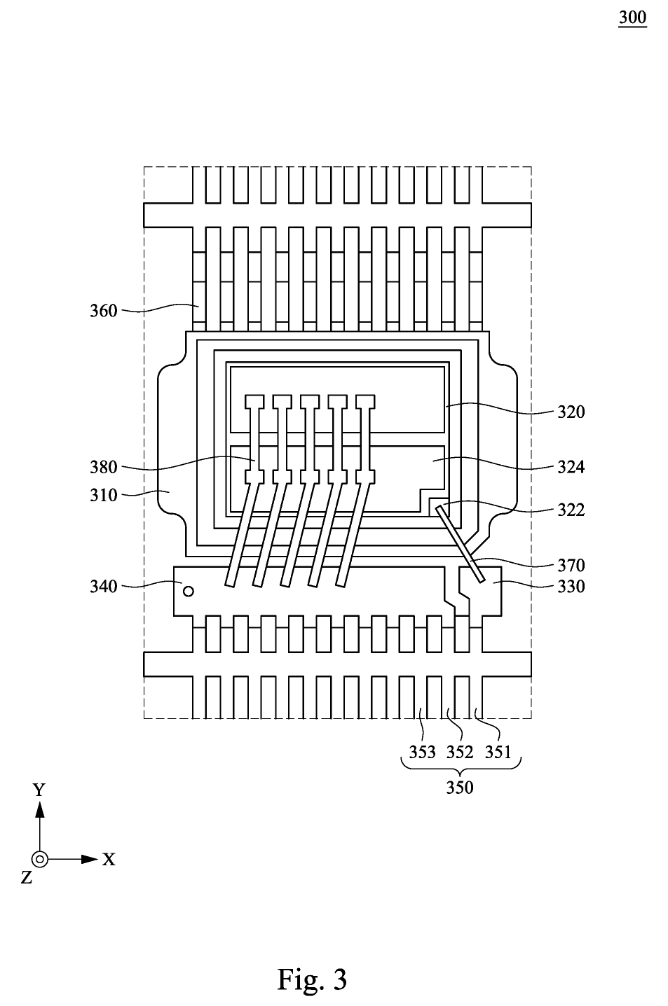

Reference is made to FIG. 3. FIG. 3 is a top view of a chip package structure 300 in accordance with an embodiment of the present disclosure. As shown in FIG. 3, in this embodiment, the chip package structure 300 includes a conductive substrate 310, a chip 320, a gate connecting part 330, a source connecting part 340, a plurality of pins 350, a drain connecting part 360, a gate conductive wire 370, and a source conductive wire 380. The chip 320 is disposed on the conductive substrate 310. The chip 320 includes a gate electrode 322, a source electrode 324, and a drain electrode (not shown). Specifically, the gate electrode 322 is separated from the source electrode 324. The drain electrode is also separated from the source electrode 324. As shown in FIG. 3, in some embodiments, the gate electrode 322 and the source electrode 324 are located on an upper surface (e.g., a front surface) of the chip 320, and the drain electrode is located on a lower surface (e.g., a back surface) of the chip 320. Therefore, in such a case, the drain electrode of the chip 320 is not visible in FIG. 3. In some embodiments, the drain electrode of the chip 320 is in contact with the conductive substrate 310. The gate connecting part 330 is located at a side of the chip 320. In some embodiments, the gate connecting part 330 is adjacent to the conductive substrate 310 and the chip 320. In some embodiments, the gate connecting part 330 is separated from the conductive substrate 310, and the gate connecting part 330 is also separated from the chip 320. The source connecting part 340 is located at a side of the chip 320. Specifically, the gate connecting part 330 and the source connecting part 340 are located at the same side of the chip 320. The source connecting part 340 is separated from the gate connecting part 330. The plurality of pins 350 are connected to the gate connecting part 330 and the source connecting part 340. In this embodiment, the plurality of pins 350 include a first pin 351, a second pin 352, and one or more third pins 353. The first pin 351 is connected to the gate connecting part 330. The second pin 352 and the one or more third pins 353 are connected to the source connecting part 340. As shown in FIG. 3, the first pin 351, the second pin 352, and the one or more third pins 353 are separated from each other. In other words, the one or more third pins 353 are connected to the second pin 352 by the source connecting part 340.

Reference is made again to FIG. 3. As shown in FIG. 3, in this embodiment, the drain connecting part 360 is connected to the conductive substrate 310. The drain connecting part 360 is located at the other side of the chip 320. In other words, the source connecting part 340 and the drain connecting part 360 are located at opposite sides of the chip 320. In some embodiments, the drain connecting part 360 is electrically connected to the drain electrode (not shown) of the chip 320 by the conductive substrate 310. The gate conductive wire 370 is connected to the gate electrode 322 of the chip 320 and the gate connecting part 330. Specifically, an end of the gate conductive wire 370 is connected to the gate electrode 322, and the other end of the gate conductive wire 370 is connected to the gate connecting part 330, such that the gate electrode 322 is electrically connected to the gate connecting part 330 by the gate conductive wire 370. The gate conductive wire 370 is electrically connected to the first pin 351 by the gate connecting part 330. The gate conductive wire 370 is separated from the source conductive wire 380. The source conductive wire 380 is connected to the source electrode 324 of the chip 320 and the source connecting part 340. Specifically, an end of the source conductive wire 380 is connected to the source electrode 324, and the other end of the source conductive wire 380 is connected to the source connecting part 340, such that the source electrode 324 is electrically connected to the source connecting part 340 by the source conductive wire 380. The source conductive wire 380 is electrically connected to the one or more third pins 353 by the source connecting part 340.

By the aforementioned structural configuration, since the second pin 352, which is configured as a sense source pin, is connected to the source connecting part 340, the volume of the source connecting part 340, which is originally connected to the one or more third pins 353, which are configured as source pins, is increased, thereby achieving the effect of enlarging the wire bonding area and increasing the quantity of bonding wires, which in turn reduces the resistance of the chip 320. Accordingly, the chip package structure 300 is feasible for applications in medium-voltage and low-voltage products.

As shown in FIG. 3, in some embodiments, the first pin 351 is located at a side of the gate connecting part 330 away from the chip 320. The second pin 352 and the one or more third pins 353 are located at a side of the source connecting part 340 away from the chip 320.

As shown in FIG. 3, in some embodiments, the second pin 352 is located between the first pin 351 and the one or more third pins 353.

In some embodiments, the quantity of the pins 350 is plural. For example, the chip package structure 300 may include eleven pins 350. However, the present disclosure is not intended to limit the quantity of the pins 350. In some embodiments in which the quantity of the pins 350 is eleven, the pins 350 include one first pin 351, one second pin 352, and nine third pins 353.

In some embodiments, the first pin 351 may be, for example, a gate pin. In some embodiments, the second pin 352 may be, for example, a sense source pin. In some embodiments, the one or more third pins 353 may be, for example, source pins.

As shown in FIG. 3, in some embodiments, the conductive substrate 310, the chip 320, and the source conductive wire 380 are sequentially arranged along a direction (e.g., a Z-direction). In some embodiments, the first pin 351, the second pin 352, and the one or more third pins 353 are arranged along a direction (e.g., an X-direction). In some embodiments, a plurality of the source conductive wires 380 are arranged along a direction (e.g., an X-direction) and are elongated in another direction (e.g., a Y-direction).

In some embodiments, the quantity of the gate conductive wire 370 may be singular. In some embodiments, the quantity of the source conductive wire 380 may be one, two, three, four, five, or more than five. However, the present disclosure is not intended to limit the quantities of the gate conductive wire 370 and the source conductive wire 380.

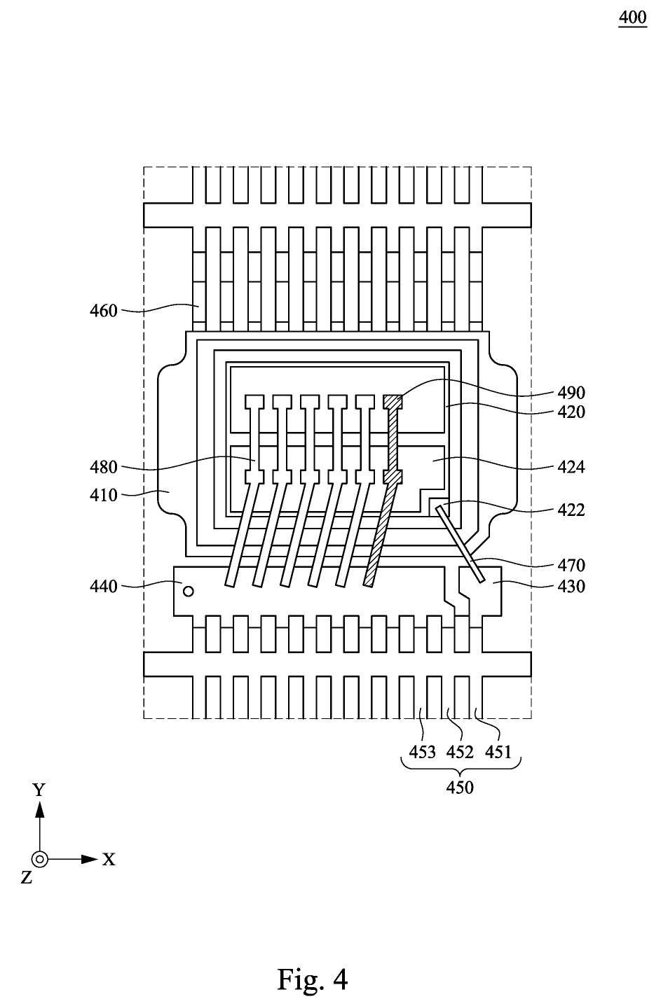

Reference is made to FIG. 4. FIG. 4 is a top view of a chip package structure 400 in accordance with an embodiment of the present disclosure. As shown in FIG. 4, in this embodiment, the chip package structure 400 includes a conductive substrate 410, a chip 420, a gate connecting part 430, a source connecting part 440, a plurality of pins 450, a drain connecting part 460, a gate conductive wire 470, a source conductive wire 480, and a sense conductive wire 490. The chip 420 is disposed on the conductive substrate 410. The chip 420 includes a gate electrode 422, a source electrode 424, and a drain electrode (not shown). It should be noted that, since the structural configuration of the chip 420 is the same as that of the chip 320, further description of the chip 420 is omitted. In some embodiments, the drain electrode of the chip 420 is in contact with the conductive substrate 410. The gate connecting part 430 is located at a side of the chip 420. In some embodiments, the gate connecting part 430 is adjacent to the conductive substrate 410 and the chip 420. In some embodiments, the gate connecting part 430 is separated from the conductive substrate 410, and the gate connecting part 430 is also separated from the chip 420. The source connecting part 440 is located at a side of the chip 420. Specifically, the gate connecting part 430 and the source connecting part 440 are located at the same side of the chip 420. The source connecting part 440 is separated from the gate connecting part 430. The plurality of pins 450 are connected to the gate connecting part 430 and the source connecting part 440. In this embodiment, the plurality of pins 450 include a first pin 451, a second pin 452, and one or more third pins 453. The first pin 451 is connected to the gate connecting part 430. The second pin 452 and the one or more third pins 453 are connected to the source connecting part 440. As shown in FIG. 4, the one or more third pins 453 are connected to the second pin 452 by the source connecting part 440.

Reference is made again to FIG. 4. As shown in FIG. 4, in this embodiment, the drain connecting part 460 is connected to the conductive substrate 410. The drain connecting part 460 is located at the other side of the chip 420. In other words, the source connecting part 440 and the drain connecting part 460 are located at opposite sides of the chip 420. In some embodiments, the drain connecting part 460 is electrically connected to the drain electrode (not shown) of the chip 420 by the conductive substrate 410. The gate conductive wire 470 is connected to the gate electrode 422 of the chip 420 and the gate connecting part 430. Specifically, an end of the gate conductive wire 470 is connected to the gate electrode 422, and the other end of the gate conductive wire 470 is connected to the gate connecting part 430, such that the gate electrode 422 is electrically connected to the gate connecting part 430 by the gate conductive wire 470. The gate conductive wire 470 is electrically connected to the first pin 451 by the gate connecting part 430. The gate conductive wire 470 is separated from the source conductive wire 480. The source conductive wire 480 is connected to the source electrode 424 of the chip 420 and the source connecting part 440. Specifically, an end of the source conductive wire 480 is connected to the source electrode 424, and the other end of the source conductive wire 480 is connected to the source connecting part 440, such that the source electrode 424 is electrically connected to the source connecting part 440 by the source conductive wire 480. The source conductive wire 480 is electrically connected to the one or more third pins 453 by the source connecting part 440.

Reference is made again to FIG. 4. As shown in FIG. 4, in this embodiment, the sense conductive wire 490 is connected to the source electrode 424 and the source connecting part 440. Specifically, the sense conductive wire 490 is connected to the source electrode 424 of the chip 420 and the source connecting part 440. Specifically, an end of the sense conductive wire 490 is connected to the source electrode 424, and the other end of the sense conductive wire 490 is connected to the source connecting part 440, such that the source electrode 424 is electrically connected to the source connecting part 440 by the sense conductive wire 490. In some embodiments, the sense conductive wire 490 is electrically connected to the second pin 452 by the source connecting part 440. The sense conductive wire 490 is separated from the source conductive wire 480, and the sense conductive wire 490 is also separated from the gate conductive wire 470.

By the aforementioned structural configuration, since the second pin 452, which is configured as a sense source pin, is connected to the source connecting part 440, the volume of the source connecting part 440, which is originally connected to the one or more third pins 453, which are configured as source pins, is increased, thereby achieving the effect of enlarging the wire bonding area and increasing the quantity of bonding wires, which in turn reduces the resistance of the chip 420. For example, the chip package structure 400 allows for the configuration of the sense conductive wire 490, thereby achieving an increased quantity of bonding wires. Accordingly, the chip package structure 400 is feasible for applications in medium-voltage and low-voltage products.

As shown in FIG. 4, in some embodiments, the first pin 451 is located at a side of the gate connecting part 430 away from the chip 420. The second pin 452 and the one or more third pins 453 are located at a side of the source connecting part 440 away from the chip 420.

As shown in FIG. 4, in some embodiments, the second pin 452 is located between the first pin 451 and the one or more third pins 453.

In some embodiments, the quantity of the pins 450 is plural. For example, the chip package structure 400 may include eleven pins 450. However, the present disclosure is not intended to limit the quantity of the pins 450. In some embodiments in which the quantity of the pins 450 is eleven, the pins 450 include one first pin 451, one second pin 452, and nine third pins 453.

In some embodiments, the first pin 451 may be, for example, a gate pin. In some embodiments, the second pin 452 may be, for example, a sense source pin. In some embodiments, the one or more third pins 453 may be, for example, source pins.

As shown in FIG. 4, in some embodiments, the conductive substrate 410, the chip 420, and the source conductive wire 480 are sequentially arranged along a direction (e.g., a Z-direction). In some embodiments, the first pin 451, the second pin 452, and the one or more third pins 453 are arranged along a direction (e.g., an X-direction). In some embodiments, the source conductive wire 480 and the sense conductive wire 490 are arranged along a direction (e.g., an X-direction) and are generally elongated along another direction (e.g., a Y-direction).

In some embodiments, the quantity of the gate conductive wire 470 may be singular. In some embodiments, the quantity of the source conductive wire 480 may be one, two, three, four, five, or more than five. In some embodiments, the quantity of the sense conductive wire 490 may be one or more than one. However, the present disclosure is not intended to limit the quantities of the gate conductive wire 470, the source conductive wire 480, and the sense conductive wire 490.

From the above detailed description of the specific embodiments of the present disclosure, it can be clearly seen that in the chip package structure of the present disclosure, since the second pin is connected to the source connecting part, the volume of the source connecting part, which is originally connected to the one or more third pins, is increased, thereby achieving the effect of enlarging the wire bonding area and increasing the quantity of bonding wires. Accordingly, the chip package structure of the present disclosure can effectively reduce the resistance of the chip to meet consumer’s demands.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A chip package structure comprising:
a conductive substrate;
a chip disposed on the conductive substrate;
a gate connecting part located at a side of the chip;
a source connecting part located at the side of the chip and separated from the gate connecting part;
a drain connecting part connected to the conductive substrate and located at the other side of the chip;
a gate conductive wire connected to a gate electrode of the chip and the gate connecting part;
a source conductive wire connected to a source electrode of the chip and the source connecting part; and
a plurality of pins connected to the gate connecting part and the source connecting part, wherein the plurality of pins comprise:
a first pin connected to the gate connecting part;
a second pin connected to the source connecting part and separated from the first pin; and
one or more third pins separated from the first pin and the second pin,
wherein the second pin is connected to the one or more third pins by the source connecting part.

2. The chip package structure of claim 1, wherein the source conductive wire is electrically connected to the one or more third pins by the source connecting part.

3. The chip package structure of claim 1, wherein the gate conductive wire is electrically connected to the first pin by the gate connecting part.

4. The chip package structure of claim 1, further comprising a sense conductive wire connected to the source electrode and the source connecting part.

5. The chip package structure of claim 4, wherein the sense conductive wire is separated from the source conductive wire.

6. The chip package structure of claim 4, wherein the sense conductive wire is electrically connected to the second pin by the source connecting part.

7. The chip package structure of claim 4, wherein the sense conductive wire is separated from the gate conductive wire.

8. The chip package structure of claim 1, wherein the gate conductive wire is separated from the source conductive wire.

9. The chip package structure of claim 1, wherein the first pin is located at a side of the gate connecting part away from the chip, and the second pin and the one or more third pins are located at a side of the source connecting part away from the chip.

10. The chip package structure of claim 1, wherein the second pin is located between the first pin and the one or more third pins.

11. A chip package structure comprising:
a conductive substrate;
a chip disposed on the conductive substrate;
a gate connecting part located at a side of the chip;
a source connecting part separated from the gate connecting part;
a drain connecting part electrically connected to a drain electrode of the chip by the conductive substrate;
a gate conductive wire connected to a gate electrode of the chip and the gate connecting part;
a source conductive wire connected to a source electrode of the chip and the source connecting part; and
a plurality of pins connected to the gate connecting part and the source connecting part, wherein the plurality of pins comprise:
a first pin connected to the gate connecting part;
a second pin connected to the source connecting part and separated from the first pin; and
one or more third pins separated from the first pin and the second pin,
wherein the second pin is connected to the one or more third pins by the source connecting part.

12. The chip package structure of claim 11, wherein the source conductive wire is electrically connected to the one or more third pins by the source connecting part.

13. The chip package structure of claim 11, wherein the gate conductive wire is electrically connected to the first pin by the gate connecting part.

14. The chip package structure of claim 11, further comprising a sense conductive wire connected to the source electrode and the source connecting part.

15. The chip package structure of claim 14, wherein the sense conductive wire is separated from the source conductive wire.

16. The chip package structure of claim 14, wherein the sense conductive wire is electrically connected to the second pin by the source connecting part.

17. The chip package structure of claim 14, wherein the sense conductive wire is separated from the gate conductive wire.

18. The chip package structure of claim 11, wherein the gate conductive wire is separated from the source conductive wire.

19. The chip package structure of claim 11, wherein the first pin is located at a side of the gate connecting part away from the chip, and the second pin and the one or more third pins are located at a side of the source connecting part away from the chip.

20. The chip package structure of claim 11, wherein the second pin is located between the first pin and the one or more third pins.
